(19) United States
(12) Patent Application Publication
(10) Pub. No.: US 2023/0247791 A1
(43) Pub. Date: Aug. 3, 2023

(54) CONTROL PANEL HOUSINGS AND GEAR ASSEMBLIES TO MOVE THE CONTROL PANEL HOUSINGS

(71) Applicant: Hewlett-Packard Development Company, L.P., Spring, TX (US)

(72) Inventor: Clinton Troy JENSEN, Boise, ID (US)

(73) Assignee: Howlett-Packard Development Company, L.P., Spring, TX (US)

(21) Appl. No.: 17/589,524

(22) Filed: Jan. 31, 2022

(51) Int. Cl. H05K 7/16; G06F 1/18; F16H 19/04; F16C 11/04

(52) U.S. Cl. CPC H05K 7/16; F16C 11/04; F16H 19/04; G06F 1/181

(57) ABSTRACT

According to examples, an apparatus may include a top cover, a control panel housing rotatably coupled to the top cover, and a gear assembly. The top cover may include an upper surface and a recess disposed on the upper surface. The control panel housing may include a first section that may house a control panel and a second section that may extend from the first section to mount the control panel housing to the top cover. In some examples, the gear assembly may be disposed in the recess. The gear assembly may include a gear rack fixed to the top cover inside the recess and a gear fixed to the second section of the control panel housing. The gear may be movably coupled to the gear rack to move along the gear rack as the control panel housing is rotated relative to the upper surface of the top cover.

### BACKGROUND

Electronic devices, such as imaging devices, may have control panels that may be mounted on the electronic devices. In some instances, the control panels may be movable, which may allow display angles of the control panels to be changed.

### BRIEF DESCRIPTION OF THE DRAWINGS

Features of the present disclosure are illustrated by way of example and not limited in the following figure(s), in which like numerals indicate like elements, in which:

FIG. 1A shows a cutaway view of an example apparatus in a lowered position, in which the apparatus may include a top cover, a control panel housing rotatably coupled to the top cover, and a gear assembly to rotatably couple the control panel housing to the top cover;

FIG. 1B shows a cutaway view of the example apparatus depicted in FIG. 1A in a raised position, in which a first section of the control panel housing to house a control panel may be positioned at a predetermined angle relative to an upper surface of the top cover;

FIG. 2 shows a perspective view of an example control panel assembly in a lowered position, in which the example control panel assembly may include a base and a control panel housing rotatably mounted to the base; and

FIG. 3 shows a perspective view of an example imaging device, which may include a top cover and a control panel assembly mounted to the top cover, in which the control panel assembly may include a control panel housing to house a control panel and a gear assembly to rotatably couple the control panel housing to the top cover.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

Electronic devices, such as imaging devices, may include control panels (CPs). Various types of mounting designs may be used to mount CPs to the electronic devices. For instance, the mounting designs may include movable types of mountings that may allow rotation of the CPs for improved viewing angles. In some examples, CPs may be mounted using a planar type mounting design, in which the CPs may be set atop a plane, such as a surface of a top cover of an imaging device. In these examples, the CPs may be rotated down, or stowed, when not in use and rotated up at an angle when in use. In some examples, the CPs may be rotated down or stowed during shipment of the electronic devices and the CPs may be rotated up at an angle in preparation of the electronic devices being used.

In some instances, planar type mounting designs may be considered to be less aesthetically desirable when folded down flat, or parallel relative to the mounting surface. The problem may lie in the hinge mechanism, which may be mounted below the mounting surface and may cause a “bulged” area in front of the CP, which may not be aesthetically desirable in some design applications.

Disclosed herein are apparatuses that may include an improved control panel housing and a gear assembly that may occupy a reduced amount of space in the control panel housing, which in turn may enable a reduction in the size of the “bulge” in the control panel housing that may be visible.

In some examples, an apparatus may include a top cover, a control panel housing rotatably coupled to the top cover, and a gear assembly. The control panel housing may include a first section to house a control panel and a second section that may extend from the first section to mount the control panel housing to the top cover. The gear assembly may be disposed in a recess on the top cover and may include a gear rack fixed to the top cover inside the recess and a gear fixed to the second section of the control panel housing. The gear may be movably coupled to the gear rack such that the gear may move along the gear rack as the control panel housing is rotated relative to the upper surface of the top cover.

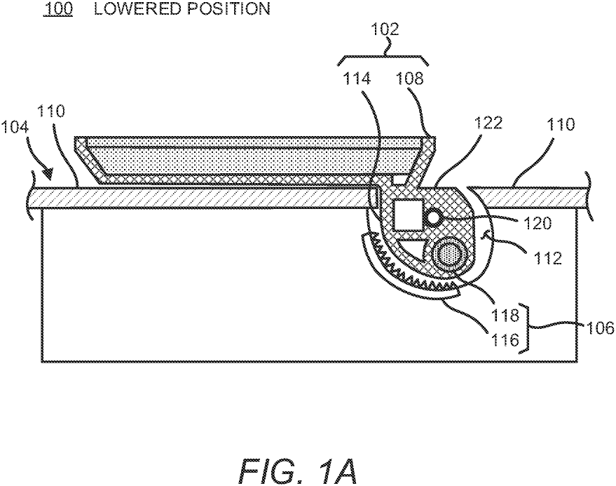

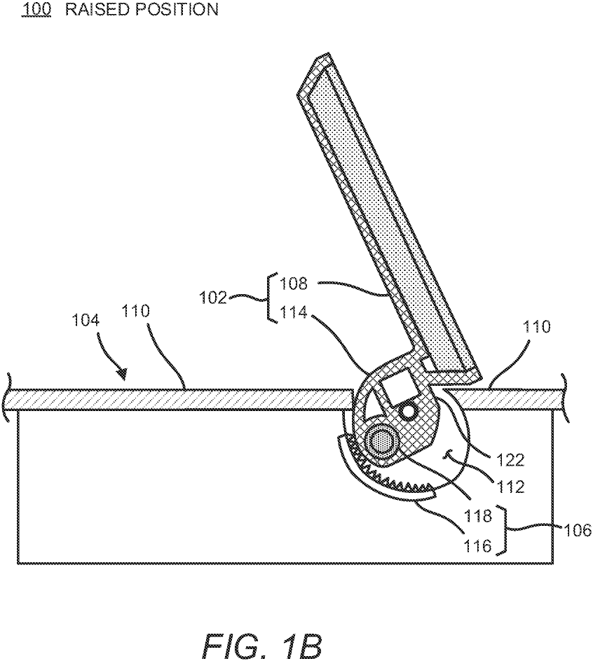

Reference is made to FIGS. 1A and 1B. FIG. 1A shows a cutaway view of an example apparatus 100 in a lowered position, in which the apparatus 100 may include a top cover 104, a control panel housing 102 rotatably coupled to the top cover 104, and a gear assembly 106 to rotatably couple the control panel housing 102 to the top cover 104. FIG. 1B shows a cutaway view of the example apparatus depicted in FIG. 1A in a raised position, in which a first section 108 of the control panel housing 102 to house a control panel may be positioned at a predetermined angle relative to an upper surface 110 of the top cover 104. It should be understood that the apparatus 100 depicted in FIGS. 1A and 1B may include additional features and that some of the features described herein may be removed and/or modified without departing from the scope of the apparatus 100.

The top cover 104 may be a base on which the control panel housing 102 may be mounted. In some examples, the top cover 104 may be a housing or a cover for an electronic device, such as an imaging device. The top cover 104 may include an upper surface 110 and a recess 112, which may be disposed on the upper surface 110.

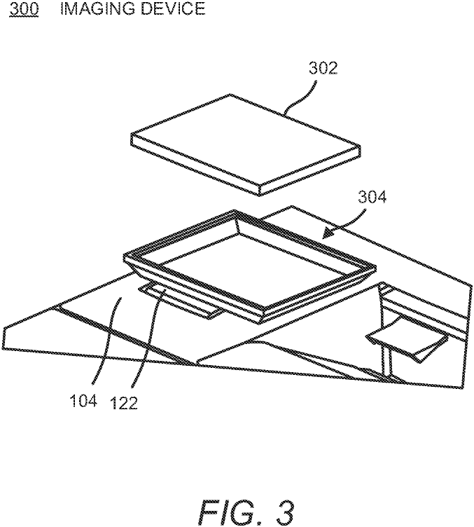

The control panel housing 102 may be rotatably coupled to the top cover 104. The control panel housing 102 may include a first section 108 and a second section 114. The first section 108 may house a control panel, such as the control panel 302 depicted in FIG. 3. The first section 108 may have a relatively flat shape, for instance, similar to a shape of a display panel. The second section 114 may extend from the first section 108. In some examples, the second section 114 may be integrally formed to the first section 108, or may be a separate component that may be attached to the first section 108. The second section 114 of the control panel housing 102 may be disposed in the recess 112 to mount the control panel housing 102 to the top cover 104.

The gear assembly 106 may be disposed in the recess 112 and may allow rotation of the control panel housing 102. The gear assembly 106 may include components that may be fixed to both the control panel housing 102 and the top cover 104. The gear assembly 106 may improve movement of the control panel housing 102, such as by improving smoothness and dampening of the motion of the control panel housing 102.

The gear assembly 106 may include a gear rack 116. The gear rack 116 may be disposed on a surface of the top cover 104, inside the recess 112. In some examples, the gear rack 116 may be integrally formed as part of the top cover 104. In other examples, the gear rack 116 may be a separate component that may be mounted to a surface of the top cover 104 inside the recess 112. The gear rack 116 may include teeth disposed along a length of the gear rack 116.

The gear assembly 106 may include a gear 118 to couple to the gear rack 116. In some examples, the gear 118 may be a pinion gear. The gear 118 may be movably coupled to the gear rack 116 to move along the gear rack 116 as the control panel housing 102 is rotated relative to the upper surface 110 of the top cover 104. The gear 118 may be rotatably fixed to the second section 114 of the control panel housing 102. In this regard, the gear 118 may rotate at a fixed positioned on the second section 114 of the control panel housing 102 as the gear 118 is moved laterally along the gear rack 116 as the control panel housing 102 is raised and lowered.

The gear 118 may have teeth that may mesh with the teeth of the gear rack 116. In some examples, the gear 118 may include a damping assembly, which may provide resistance to dampen a motion of the gear 118. In this regard, the gear 118 may be loaded with a compressed spring and clutch plates, or clutch faces (not shown), against the gear 118. In some examples, the gear assembly 106 may be eccentrically located relative to a rotational axis 120 of the control panel housing 102, which may provide a gear-down capability.

In some examples, the control panel housing 102 may be positioned in a first position, or a lowered position, in which the control panel housing 102 may be substantially parallel to the upper surface 110 of the top cover 104, as depicted in FIG. 1A. The control panel housing 102 may be moved or rotated from the first position to a second position, or a raised position, in which the control panel housing 102 may be angled at a predetermined angle relative to the upper surface 110 of the top cover 104, as depicted in FIG. 1B.

When the control panel housing 102 is positioned in the lowered position, the gear 118 may be positioned at a first height below a rotational axis 120 of the control panel housing 102. From the first position, the gear 118 may move around the rotational axis 120 of the control panel housing 102, for instance in an eccentric path, and may be positioned at a second height above the first height when the control panel housing 102 is rotated from the first position to the second position. In some examples, the gear 118 may be positioned at a lower end of the gear rack 116 when the control panel housing 102 is in the first position, and when the control panel housing 102 is rotated to be positioned in the second position, the gear 118 may be positioned at an upper end of the gear rack 116.

In some examples, the control panel housing 102 may include a front surface 122. The front surface 122 may be disposed on a front side of the control panel housing 102. In some instances, the front surface 122 may be visible when the control panel housing 102 is positioned in the lowered position depicted in FIG. 1A. In some examples, the front surface 122 may be disposed on the second section 114 of the control panel housing 102.

When the control panel housing 102 is in the lowered position, the first section 108 of the control panel housing 102 may be disposed outside of the recess 112 and angled to be substantially parallel to the upper surface 110 of the top cover 104. When the control panel housing 102 is in the raised position, the first section 108 of the control panel housing 102 may be disposed outside of the recess 112 and angled at a predetermined angle relative to the upper surface 110 of the top cover 104.

In some examples, the second section 114 of the control panel housing 102 may be disposed inside the recess 112 when the control panel housing 102 is in the lowered position and the raised position. The front surface 122 may be exposed through the recess 112 when the control panel housing 102 is in the lowered position. When the control panel housing 102 is rotated to the raised position, the front surface 122 of the second section 114 may be positioned inside the recess 112 as shown in FIG. 1B.

When the control panel housing 102 is in the lowered position, a portion of the second section 114 of the control panel housing 102 may be visible, for instance, the front surface 122. The front surface 122 may be substantially flat. When the control panel housing 102 is in the lowered position, the front surface 122 may be substantially coplanar to the upper surface 110 of the top cover 104. In some examples, the front surface 122 may extend above the upper surface 110, outside of the recess 112, a predetermined distance or height. In these instances, the front surface 122 may be parallel to the upper surface 110 when the control panel housing 102 is in the lowered position.

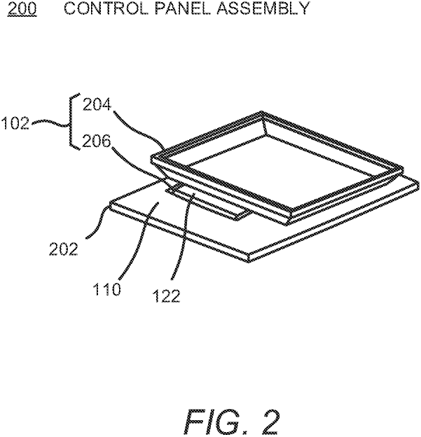

Reference is now made to FIG. 2, which shows a perspective view of an example control panel assembly 200 in a lowered position, in which the example control panel assembly 200 may include a base 202 and a control panel housing 102 rotatably mounted to the base 202. The description of the example control panel assembly 200 is made with reference to the features depicted in FIGS. 1A and 1B for purposes of illustration. It should be understood that the control panel assembly 200 may include additional features and that some of the features described herein may be removed and/or modified without departing from the scope of the control panel assembly 200.

The control panel assembly 200 may include a base 202. In some examples, for instance when the control panel assembly 200 is to be mounted to an electronic device, the base 202 may be the same as the top cover 104 depicted in FIGS. 1A and 1B. The base 202 may have a recess 112 on an upper surface 110 of the base 202.

The control panel assembly 200 may include a control panel housing, such as the control panel housing 102 depicted in FIGS. 1A and 1B. The control panel housing 102 may be rotatably mounted to the base 202 to rotate between a first position, or a lowered position, and a second position, or a raised position.

The control panel housing 102 may include a control panel section 204 and a gear assembly section 206. The control panel section 204 and the gear assembly section 206, respectively, may be the same as the first section 108 and the second section 114 depicted in FIGS. 1A and 1B.

The control panel section 204 may be disposed outside of the recess 112 on the upper surface 110 of the base 202 and may be angled to extend along the upper surface 110 when the control panel housing 102 is in the lowered position. The control panel section 204 may be angled at a predetermined angle relative to the upper surface 110 when the control panel housing 102 is in the raised position.

The gear assembly section 206 may be disposed inside the recess 112 on the upper surface 110 of the base 202. The gear assembly section 206 may have a front surface 122 that may be exposed through the recess 112, and may be visible when the control panel housing 102 is in the lowered position. The front surface 122 may be substantially parallel to the upper surface 110 when the control panel housing 102 is in the lowered position and may be disposed inside the recess 112 when the control panel housing 102 is in the raised position. In some examples, when the control panel housing 102 is in the lowered position, the front surface 122 may be substantially coplanar to the upper surface 110 of the base 202.

In some examples, the control panel assembly 200 may include a gear rack 116 and a gear 118. The gear rack 116 may be fixed to the base 202 inside the recess 112. The gear 118 may be fixed to the gear assembly section 206 of the control panel housing 102. The gear 118 may be movably coupled to the gear rack 116 to move along the gear rack 116 as the control panel housing 102 is rotated relative to the upper surface 110 of the base 202.

The gear 118 may be positioned at a lower end of the gear rack 116 when the control panel housing 102 is in the lowered position and may be positioned at an upper end of the gear rack 116 when the control panel housing 102 is moved to the raised position. For instance, the gear rack 116 may be disposed inside the recess 112 to extend toward the upper surface 110, for instance, in a vertical direction toward the upper surface 110. In this instance, the lower end of the gear rack 116 may be an end of the gear rack 116 that is disposed farther inside the recess 112 and the upper end of the gear rack 116 may be an end of the gear rack 116 that is closer to an opening of the recess 112.

Reference is now made to FIG. 3, which shows a perspective view of an example imaging device 300, which may include a top cover 104 and a control panel assembly 304 mounted to the top cover 104, in which the control panel assembly 304 may include a control panel housing 102 to house a control panel 302 and a gear assembly 106 to rotatably couple the control panel housing 102 to the top cover 104. The description of the example imaging device is made with reference to the features depicted in FIGS. 1A, 1B, and 2 for purposes of illustration. It should be understood that the imaging device 300 may include additional features and that some of the features described herein may be removed and/or modified without departing from the scope of the imaging device 300.

The imaging device 300 may include a top cover, such as the top cover 104 depicted in FIGS. 1A and 1B, and a control panel assembly 304 mounted to the top cover. In some examples, the top cover 104 may be a part of a body of the imaging device 300, such as a cover panel, and/or the like. The top cover 104 may form a base on which to mount the control panel assembly 304.

The control panel assembly 304 may be the same as the control panel assembly 200 depicted in FIG. 2. In some examples, the control panel assembly 304 may include a control panel housing, such as the control panel housing 102 depicted in FIGS. 1A, 1B, and 2. The control panel housing 102 may include a control panel section 204 to house a control panel 302. The control panel housing 102 may include a gear assembly section 206 that may extend from the control panel section 204 and may be mounted to the top cover 104.

In some examples, the gear assembly section 206 may have a front surface 122 that may be exposed through the top cover 104 and may be visible when the control panel housing 102 is in a lowered position. In this instance, when the control panel housing is in the lowered position, the front surface 122 may extend along the top cover 104 and may be substantially parallel to the top cover 104.

In some examples, the top cover 104 and the front surface 122 may have planar or flat surfaces. In these instances, when the control panel housing 102 is in the lowered position, the front surface 122 of the gear assembly section 206 may be substantially coplanar to the top cover 104. In some examples, the front surface 122 may be moved under the top cover 104 when the control panel 302 is rotated to a raised position. In this instance, the front surface 122 may be hidden by the top cover 104 and may not be visible.

The control panel assembly 304 may include a gear assembly 106 to rotatably couple the control panel housing 102 to the top cover 104. The gear assembly 106 may include a gear rack 116 fixed inside the top cover 104 and a pinion gear, such as the gear 118 depicted in FIGS. 1A and 1B, fixed to the gear assembly section 206 of the control panel housing 102.

In some examples, the gear 118 may rotate as the gear is moved laterally along the gear rack 116 when the control panel housing 102 is moved between the lowered position and the raised position. The gear 118 may be positioned at a lower end of the gear rack 116 when the control panel housing 102 is in the lowered position and the gear 118 may be positioned at an upper end of the gear rack 116 when the control panel housing 102 is in the raised position.

Although described specifically throughout the entirety of the instant disclosure, representative examples of the present disclosure have utility over a wide range of applications, and the above discussion is not intended and should not be construed to be limiting, but is offered as an illustrative discussion of aspects of the disclosure.

What has been described and illustrated herein is an example of the disclosure along with some of its variations. The terms, descriptions and figures used herein are set forth by way of illustration and are not meant as limitations. Many variations are possible within the scope of the disclosure, which is intended to be defined by the following claims - and their equivalents - in which all terms are meant in their broadest reasonable sense unless otherwise indicated.

What is claimed is:

1. An apparatus comprising:
a top cover including:
an upper surface; and
a recess disposed on the upper surface;
a control panel housing rotatably coupled to the top cover, the control panel housing comprising:
a first section to house a control panel; and
a second section that extends from the first section to mount the control panel housing to the top cover; and
a gear assembly disposed in the recess, the gear assembly comprising:
a gear rack fixed to the top cover inside the recess; and
a gear fixed to the second section of the control panel housing, the gear being movably coupled to the gear rack to move along the gear rack as the control panel housing is rotated relative to the upper surface of the top cover.

2. The apparatus of claim 1, wherein the control panel housing is to rotate from a first position in which the control panel housing is substantially parallel to the upper surface of the top cover to a second position in which the control panel housing is angled at a predetermined angle relative to the upper surface of the top cover.

3. The apparatus of claim 2, wherein the gear is positioned at a first height below a rotational axis of the control panel housing when the control panel housing is in the first position, and the gear is to rotate around the rotational axis of the control panel housing and be positioned at a second height above the first height when the control panel housing is rotated from the first position to the second position.

4. The apparatus of claim 2, wherein the gear is rotatably fixed to the second section of the control panel housing, the gear to rotate as the gear is moved laterally along the gear rack when the control panel housing is rotated from the first position to the second position.

5. The apparatus of claim 2, wherein the gear is positioned at a lower end of the gear rack when the control panel housing is in the first position and the gear is positioned at an upper end of the gear rack when the control panel housing is in the second position.

6. The apparatus of claim 1, wherein:
when the control panel housing is in a first position, the first section of the control panel housing is disposed outside of the recess and angled to be substantially parallel to the upper surface of the top cover; and
when the control panel housing is in a second position, the first section of the control panel housing is disposed outside of the recess and angled at a predetermined angle relative to the upper surface of the top cover.

7. The apparatus of claim 6, wherein the second section of the control panel housing is disposed inside the recess when the control panel housing is in the first position and the second position.

8. The apparatus of claim 6, wherein the second section of the control panel housing comprises:
a front surface that is exposed through the recess when the control panel housing is in the first position, and the front surface is positioned inside the recess when the control panel is rotated to the second position.

9. The apparatus of claim 8, wherein, when the control panel housing is in the first position, the front surface is substantially coplanar to the upper surface of the top cover.

10. A control panel assembly comprising:
a base having a recess on an upper surface of the base; and
a control panel housing rotatably mounted to the base to rotate from a first position to a second position, the control panel housing comprising:
a control panel section that is disposed outside of the recess on the upper surface of the base and angled to extend along the upper surface when the control panel housing is in the first position, and angled at a predetermined angle relative to the upper surface when the control panel housing is in the second position; and
a gear assembly section that is disposed inside the recess on the upper surface of the base, the gear assembly section having a front surface that is substantially parallel to the upper surface when the control panel housing is in the first position and is disposed inside the recess when the control panel housing is in the second position.

11. The control panel assembly of claim 10, wherein, when the control panel housing is in the first position, the front surface is exposed through the recess and is substantially coplanar to the upper surface of the base.

12. The control panel assembly of claim 10, further comprising:
a gear rack fixed to the base inside the recess; and
a gear fixed to the gear assembly section of the control panel housing, the gear being movably coupled to the gear rack to move along the gear rack as the control panel housing is rotated relative to the upper surface of the base,
wherein the gear is positioned at a lower end of the gear rack when the control panel housing is in the first position and is positioned at an upper end of the gear rack when the control panel housing is moved to the second position.

13. An imaging device comprising:
a top cover; and
a control panel assembly mounted to the top cover, the control panel assembly comprising:
a control panel housing comprising a control panel section to house a control panel, and a gear assembly section that extends from the control panel section and is mounted to the top cover, the gear assembly section having a front surface that is substantially parallel to the top cover when the control panel housing is in a lowered position; and
a gear assembly to rotatably couple the control panel housing to the top cover, the gear assembly comprising a gear rack fixed inside the top cover and a pinion gear fixed to the gear assembly section of the control panel housing.

14. The imaging device of claim 13, wherein the front surface of the gear assembly section is exposed through the top cover when the control panel housing is in the lowered position, and the front surface is moved under the top cover when the control panel is rotated to a raised position, wherein, when the control panel housing is in the lowered position, the front surface of the gear assembly section is substantially coplanar to the top cover.

15. The imaging device of claim 13, wherein the pinion gear is to rotate as the pinion gear is moved laterally along the gear rack when the control panel housing is moved between the lowered position and a raised position, wherein the pinion gear is positioned at a lower end of the gear rack when the control panel housing is in the lowered position and the pinion gear is positioned at an upper end of the gear rack when the control panel housing is in the raised position.
